(19) United States
(12) Patent Application Publication
(10) Pub. No.: US 2007/0026650 A1
(43) Pub. Date: Feb. 1, 2007

(54) Method of limiting vacancy diffusion in a heterostructure

(76) Inventor: Xavier Hebras, Grenoble (FR)

Correspondence Address: WINSTON & STRAWN LLP;PATENT DEPARTMENT, 1700 K STREET, N.W., WASHINGTON, DC, 20006, US

(21) Appl. No.: 11/521,146

(22) Filed: Sep. 13, 2006

Related U.S. Application Data
(63) Continuation of application No. 10/976,172, filed on Oct. 28, 2004, now Pat. No. 7,107,927.

(30) Foreign Application Priority Data
Jun. 9, 2006 (FR) 06/52083

(51) Int. Cl. H01L 21/385

(52) U.S. Cl. 438/514; 438/558

(57) ABSTRACT

A method of fabricating a heterostructure comprising at least a first layer of semi-conductor material such as, for example, a silicon-germanium (SiGe) layer on a second layer or a substrate of another material. The material of the second layer may differ from that of the first layer. To prevent elements of the semiconductor material of the first layer from diffusing into the first layer as well as the adjacent layers by a vacancy mechanism, the first layer may be enriched with interstitial defects to limit vacancy diffusion of elements of the first layer.

### FIELD OF THE INVENTION

The present invention relates to semiconductor wafers and, more particularly, semi-conductor wafers produced from heterostructures including a first layer of semiconductor material on a second layer or a substrate of another material, generally an insulator.

### BACKGROUND OF THE INVENTION

A SiGe/Si type heterostructure may be used directly to form a layer of semiconductor material such as in a SiGeOI type (silicon-germanium (SiGe) on insulator) structure. Alternatively, a SiGe/Si type heterostructure may be used as a layer for epitaxial growth, in particular, to form a strained silicon layer, such as during the production of a sSOI (strained silicon on insulator) type structure.

In the semiconductor field, there is a growing interest in heterostructures of the SiGe/Si type or heterostructures including a strained silicon layer (sSi). As a result of either germanium being present or the material being strained, heterostructures have electrical characteristics which are more interesting than those of standard structures produced from silicon. The quality of films on the surface of such semiconductor structures is of vital importance. In particular, the absence of defects and contaminants on the surface or in the thickness of the structures are parameters that must be optimized when considering the fabrication of future components.

For example, in the case of fabricating a sSOI type substrate using the SMART-CUT® technique (such as described in U.S. Pat. No. 5,374,564 or in A. J. Auberton-Herve, “Why Can SMART-CUT® Change the Future of Microelectronics?,” Int. Journal of High Speed Electronics and Systems, Vol. 10, No. 1, 2000, pp. 131-146), a first operation consists of producing a donor substrate formed by a Si/SiGe/Si type heterostructure (FIG. 1A). After growing a SiGe buffer layer on a silicon support substrate, fabrication of the donor substrate includes producing a SiGe layer which is relaxed because of the SiGe buffer layer. Next, a strained silicon layer (sSi) is formed on the relaxed SiGe layer. The concentration of Ge in the relaxed layer is typically of the order of 20%, but it may attain 100% depending on the degree of strain desired in the silicon film.

When using the SMART-CUT® technique, once the sSi layer has been formed, atomic species are implanted in the relaxed SiGe layer in an implantation zone. The face of the sSi layer is brought into intimate contact with a support substrate (in general a Si substrate). The SiGe layer is then split at the implantation zone to transfer the portion located between the surface which underwent implantation and the implantation zone (i.e., the sSi layer and a portion of the relaxed SiGe layer) to the receiving substrate. After removing the remaining SiGe subsisting above the sSi layer, a sSOI structure is obtained with a sSi layer on one face of the support substrate (FIG. 1B).

The production of a sSOI structure using the SMART-CUT® technique has been described in U.S. Pat. No. 6,953,736. Such a fabrication method employs treatments that bring about degradation resulting from the diffusion of elemental germanium within the structure (FIGS. 1A to 2C). For example, heat treatments, which are performed during the formation on the donor substrate of the strained silicon layer and the oxide layer (FIG. 2B) and/or during transfer of the layers of sSi and SiGe (FIG. 2C), contribute to the diffusion of elemental germanium into the strained silicon layer. SMART-CUT® involves heat treatments such as, for example, densification of the deposited oxide, splitting or weakening heat treatment, and any post-splitting heat treatments which precede etching (strengthening pre-stabilization of the bonding interface at about 800° C. for a few hours). These heat treatments are important and should not be limited to avoid diffusion of elemental germanium, in particular when germanium concentration exceeds 20%.

Diffusion of a fraction of the elemental germanium from the SiGe layer into the sSi layer results in a lack of demarcation between the SiGe layer and the sSi layer, which causes problems when carrying out the selective etches. As a result, the transition from a SiGe zone to a silicon zone (e.g., a change of Ge concentration from 40% to 0) does not occur in an abrupt manner but extends over a certain thickness as a result of the diffusion of germanium into the adjacent strained silicon layer.

In order to remove all of the germanium present in the stained silicon layer, selective etching of germanium at the strained silicon layer must be prolonged for a long period. Since removing all of the transitional zone containing germanium results in over-etching of the strained silicon layer, in particular, at defects or weak zones (dislocations, crystalline defects, impurities or contaminants, lack of uniformity as regards thickness) in the transferred layer, excessively extending the etching step leads to the formation of a rough post-etching surface, or even to the formation of HF defects. HF defects are defects in the active semiconductor layer of the sSOI structure, in this case the sSi layer, which extend from the surface of the layer to the buried oxide layer. The presence of the defects may be revealed by an etch pit decoration after treatment with hydrofluoric acid (HF). It is important to be able to control the quality of the strained silicon layer with great precision because that layer is thin (of the order of 200 Å [Angstroms] for SiGe containing 20% Ge).

Studies have shown that there is a direct relationship between the diffusion of species within SiGe structures and the presence of point defects of the vacancy and/or interstitial type. As shown in FIG. 3A, a vacancy type point defect is shown by a site A (vacancy) of a crystalline lattice 10 which is not occupied. The diffusion mechanism involving vacancy type point defects (vacancy mechanism) corresponds to occupation of a vacancy by a neighboring atom 11 which can “jump” to that site, causing a vacancy to appear at the site it has just left, site B in FIG. 3B. As a result, in a Si/SiGe type heterostructure, the presence of vacancies in the crystalline lattice combined with the application of heat treatments will, by linking up the jumps between the vacancies, cause the germanium atoms to be displaced within the structure and thus result in their diffusion, known as vacancy type diffusion.

Moreover, an interstitial type point defect results from an interstitial atom jumping from one interstitial site to another interstitial site (i.e., sites between the substitutional sites of the crystalline lattice). This is known as a direct interstitial mechanism. When the atom under consideration may be found in a substitutional and an interstitial position, the diffusion mechanism becomes an indirect interstitial mechanism (or interstitialcy diffusion). As shown in FIGS. 4A to 4C, for an indirect interstitial mechanism, when an atom 22 of a crystalline lattice 20 is positioned at a substitution site, the atom 22 can only jump if an interstitial 21 comes into a neighboring position (FIG. 4A) and, thereby, evicts the atom 22 from its site (FIG. 4B), which then places it in an interstitial position (FIG. 4C). Atom 22 may then jump to any neighboring substitutional site, thereby creating an interstitial defect.

In Griglione et al., “Diffusion of Ge in Si₁₋ₓGeₓ/Si single quantum wells in inert and oxidizing ambients,” JAP, 88, 3, 1366-1372 (August 2000), the authors studied the diffusion of germanium in a Si/SiGe/Si heterostructure in an oxidizing atmosphere and in an inert atmosphere (Ar/N₂). The results show that the germanium diffusion profiles are the same regardless of the nature of the medium and the applied temperature. According to the article, the presence of vacancies greatly encourages the diffusion of germanium, while the presence of interstitials does not play a major role in diffusion.

Vacancy type diffusion phenomenon has also been observed in heterostructures other than those of the SiGe/Si type. For example, in a heterostructure formed by a layer of silicon-antimony (Sb) alloy (such as SiₓSb_{y}) or a layer doped with antimony on a silicon substrate, the elemental antimony diffuses into the silicon almost exclusively by the vacancy mechanism. Similarly, in a heterostructure formed by a layer of a silicon-tin (Sn) alloy (such as SiₓSn_{y}), or a layer doped with tin on a silicon substrate, about 60% to 80% of the tin diffuses into the silicon substrate by the vacancy mechanism. In general, diffusion in metals principally occurs by the vacancy mechanism.

It is desirable to overcome the problem of vacancy diffusion of elements in a hetero-structure, and this is now provided by the present invention.

### SUMMARY OF THE INVENTION

The invention relates to a method of fabricating a heterostructure which comprises forming at least a first layer of semiconductor material on a second layer of a material, the second layer of material may differ from that of the first layer. The elements of the semi-conductor material may be capable of diffusing into the second layer by a vacancy mechanism. In order to limit diffusion of the elements of the first layer, the first layer may be enriched with interstitial defects. By enriching (i.e., over-saturating) the semiconductor layer with interstitial defects, a large quantity of interstitials are available to occupy the vacant sites. In this way, vacancy type diffusion of elements of the semiconductor material of the first layer into the first layer and the adjacent second layer may be prevented even during subsequent heat treatments.

In one embodiment, the first layer may be a layer of silicon-germanium (SiGe) and the second layer may be a silicon substrate. The method may include at least one step of ion implantation in the SiGe layer to form a zone of weakness at a predetermined depth in the SiGe layer. The SiGe layer may be enriched with interstitial defects during the enrichment step. Enriching, for example, by supersaturating the SiGe layer with interstitial defects may compensate for the supersaturation of vacancies created by ion implantation to form the zone of weakness. The interstitials may occupy the vacant sites and, as a result, may prevent vacancy type diffusion of the elemental germanium of the SiGe layer in the SiGe layer as well as adjacent layers, even during subsequent heat treatments. As a result, in one embodiment, a strained silicon layer may be formed on the treated SiGe layer without risking diffusion of elemental germanium into the strained silicon layer.

In one method, the step of interstitial defect enrichment of the SiGe layer may be carried out by ion implantation of silicon atoms into the SiGe layer. During the ionic implantation of silicon atoms into the SiGe layer, the implantation energy and the implantation dose may be selected to form a silicon-enriched layer, which may be located between the zone of weakness and the surface of the SiGe layer and which may have a maximum concentration of silicon atoms between about 1×10²⁰ atoms/cm³ and about 5×10²¹ atoms/cm³. In another embodiment, the step of interstitial defect enrichment in the SiGe layer may be carried out by oxidizing the surface of the SiGe layer.

The method described herein may be carried out to form a sSOI type structure. In one embodiment, the SiGe layer may be a relaxed SiGe layer on a silicon substrate and the method may further comprise forming a strained silicon layer on the SiGe layer; bonding the strained silicon layer to a support substrate; detaching the SiGe layer at the zone of weakness by splitting; and selectively etching the remaining SiGe subsisting above the strained silicon layer following detachment. When the interstitial defects are formed in the SiGe layer by ion implantation, the ion implantation may be carried out before or after the implantation step, which forms the weakened zone, and/or before or after the step of forming the strained silicon layer on the SiGe layer. Alternatively, when the interstitial defects are formed in the SiGe layer by oxidizing the surface of the SiGe layer, the oxidation may be carried out before or after the step of forming the strained silicon layer on the SiGe layer and before the implantation step to form the weakened layer.

### BRIEF DESCRIPTION OF THE DRAWINGS

The present invention can be better understood by reference to the following drawings, wherein like references numerals represent like elements. The drawings are merely exemplary to illustrate certain features that can be used singularly or in combination with other features and the present invention should not be limited to the embodiments shown.

FIGS. 1A and 1B is an exemplary embodiment of conventional fabrication of a sSOI structure type using the SMART-CUT® technique (PRIOR ART);

FIGS. 2A to 2C is an exemplary embodiment of diffusion of germanium within a sSOI type structure during conventional fabrication of the structure (PRIOR ART);

FIGS. 3A and 3B is an exemplary embodiment of a conventional diffusion mechanism resulting in vacancy type point defects (PRIOR ART);

FIGS. 4A to 4C is an exemplary embodiment of a diffusion mechanism resulting in interstitial type point defects (PRIOR ART);

FIGS. 5A to 5D illustrates the formation of nano-bubbles in a silicon layer after helium ion implantation as well as the transformation of nano-bubbles into vacancy type defects after applying heat treatments according to the present invention;

FIGS. 6A to 6G are diagrammatic sectional views showing an exemplary method for forming a sSOI type structure according to the invention;

FIG. 7 is a flow chart of the steps of FIGS. 6A to 6G;

FIGS. 8A to 8H are diagrammatic sectional views showing another exemplary method for forming a sSOI type structure according to the invention; and

FIG. 9 is a flow chart of the steps of FIGS. 8A to 8H.

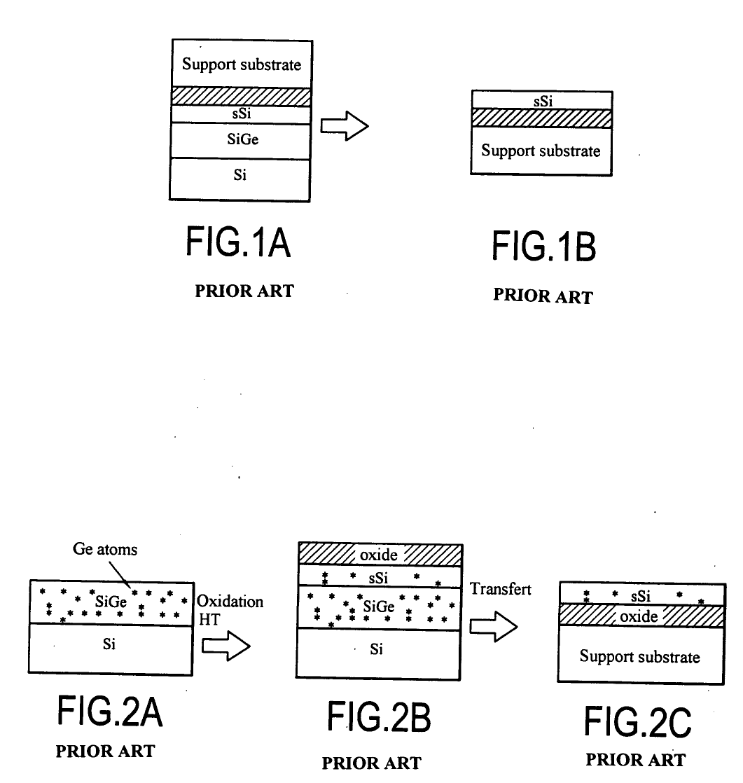

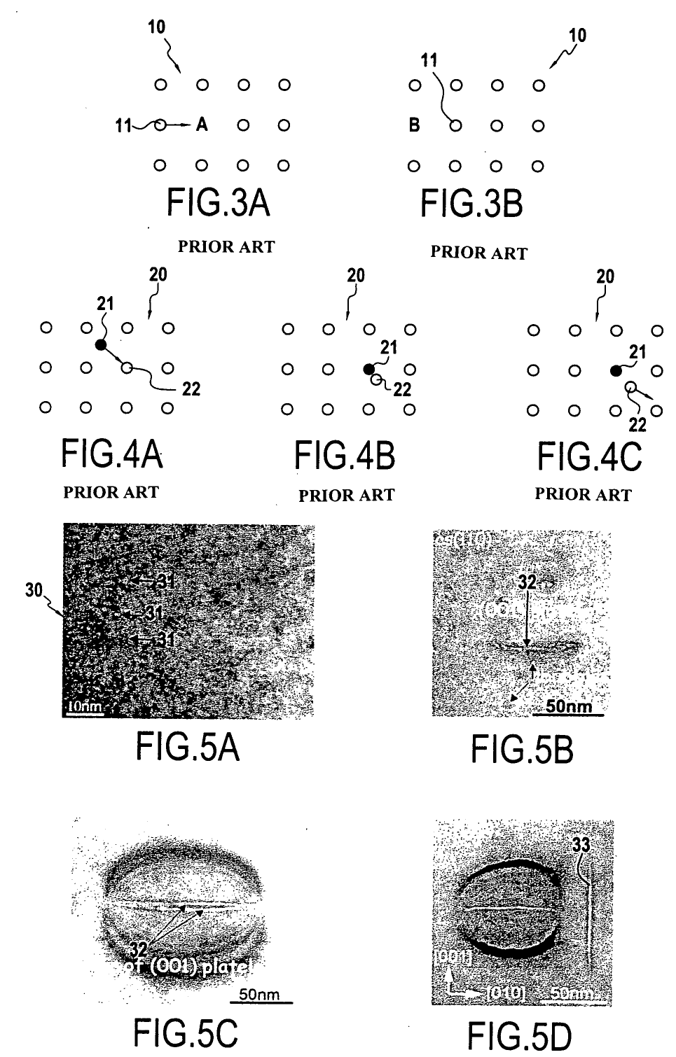

### DETAILED DESCRIPTION OF THE PREFERRED EMBODIMENTS

The present invention relates to a method of controlling the vacancy diffusion of elements such as, for example, germanium atoms in a semiconductor material (e.g., a silicon-germanium (SiGe) layer). The method restricts the displacement of elements in the semi-conductor layer and, thereby, may prevent passage of elements into the adjacent layers of the semiconductor layer.

In general, the method of the present invention is applicable to any type of hetero-structure comprising a layer of semiconductor material containing elements which can diffuse by a vacancy mechanism into the semiconductor material layer as well as adjacent layers. In particular, diffusion may take place following treatments such as, for example, heat treatments which may involve forming vacancies, thereby encouraging the vacancy diffusion of elements. In one embodiment, the method described herein can be applied to heterostructures formed by a layer of antimony (Sb) alloy (e.g., SiₓSb_{y}) or a layer doped with antimony on a silicon substrate. Alternatively, the method may be applied to heterostructures formed by a layer of tin alloy (Sn) (e.g., SiₓSn_{y}) or a layer doped with tin on a silicon substrate.

In a preferred embodiment, the invention may be applicable to heterostructures containing at least one layer of silicon-germanium (SiGe) on a silicon substrate, wherein the germanium concentration may be between 1% and 100%. A layer of SiGe may be prone to containing vacancy type defects, thereby encouraging the diffusion of germanium atoms into the SiGe layer and adjacent layers. In particular, such layers may correspond to layers of SiGe which have undergone or will undergo ion implantation (e.g., implanting He and/or H species) to form a zone of weakness in order to split (fracture) the layer. It should be appreciated, however, that the invention may pertain to any type of donor substrate which may comprise a relaxed SiGe layer used to form a layer of strained silicon (sSi). More particularly, the invention may pertain to donor substrates in which the SiGe layer has a significant germanium content and which are more sensitive to diffusion due to a high germanium concentration. The SiGe layer in donor substrates may contain between 20% to 50% germanium, however, the concentration of germanium may be as high 100%, depending on the desired strain in the sSi layer.

Vacancy type defects (hereinafter termed “vacancies”) as well as interstitial type defects (hereinafter termed “interstitials”) may be present in SiGe layers. There is an equilibrium between the concentration of vacancies, Cv, and the concentration of interstitials, Ci, in a substrate. Thus, the equilibrium may be defined by the formula Cv×Ci=constant. The equilibrium, however, may be modified during the implantation steps (e.g., implantation of hydrogen and/or helium), which may be performed to create a zone of weakness to allow a transfer of layers using the SMART-CUT® technique. Nano-bubbles may be created in the SiGe layer and will evolve into agglomerates of vacancies during the various anneals applied during the fabrication method, thereby creating a supersaturation of vacancies in the substrate. Germanium, which principally diffuses by the “vacancy mechanism,” will be positioned in the vacancies to diffuse within the substrate.

FIG. 5A shows the presence of agglomerates of vacancies 31 obtained after implantation into a silicon substrate 30 of helium ions (implantation conditions: implantation energy=32 keV [kilo electron volt], He dose=1×10¹⁶ atoms/cm²). FIGS. 5B to 5D show the transformation of nano-bubbles into horizontal “platelet” type defects in the [100] planes (cubic structure planes) (FIGS. 5B and 5C) and into vertical platelet type defects 33 in the [010] planes (FIG. 5D) after annealing the implanted silicon substrate 30 at 350° C. for 3 minutes. These objects (platelets), which are filled with gas in the first stage of their development, will dissolve, producing vacancies. The platelets, which are the source of vacancies, have also been observed in SiGe or germanium substrates.

To prevent the migration of vacancies and, as a result, the diffusion of germanium, the substrate containing the SiGe layer may be enriched with interstitials to compensate for the vacancy supersaturation by recombination of the vacancy/interstitial pairs. The substrate may be enriched with interstitials by various methods. Generally, additional elements are injected into the semiconductor material of the first layer in an amount sufficient to create interstitial defects therein to limit or prevent vacancy diffusion of the elements into the second layer.

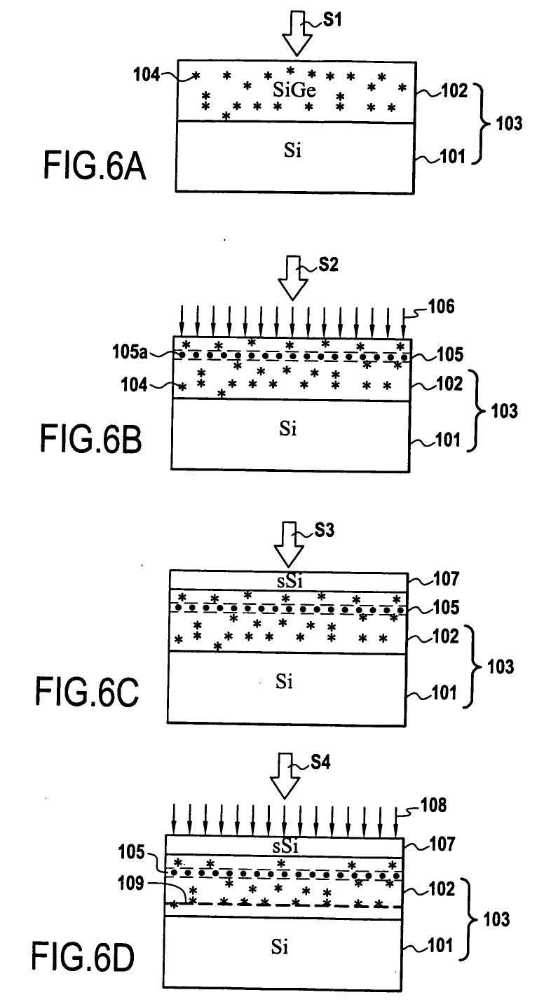

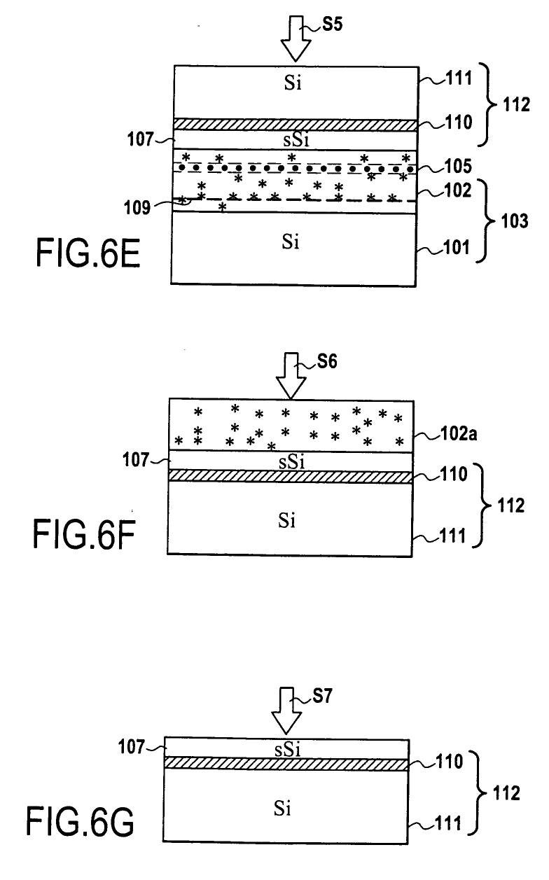

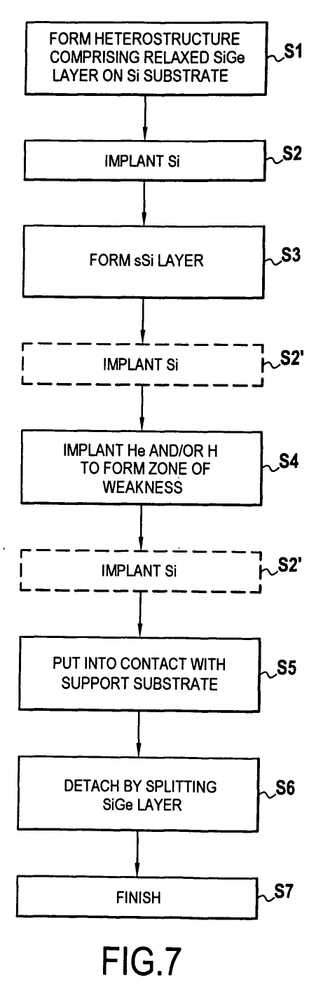

In a first exemplary method, as shown in FIGS. 6A to 6G and 7 enrichment may be carried out by ion implantation. The first method may be implemented during the production of a wafer of the sSOI type by the SMART-CUT® technique. The first step (S1) may involve forming a heterogeneous structure 103, shown in FIG. 6A, which may comprise a support substrate 101 of silicon and a relaxed SiGe layer 102 formed from a SiGe buffer layer (not shown). The heterogeneous structure may be made by any method know in the art. The layer 102 may comprise a quantity of elemental germanium 104 such as, for example, between 20% and 50% of the composition of the SiGe layer 102. The thickness of the SiGe layer may be between, for example, 0.1 μm [micrometer] and 1 μm.

Elements may be implanted to enrich a zone located between the maximum implantation forming the zone of weakness for splitting (subsequently formed in step S4) and the interface between the SiGe layer and the sSi layer. The dose of the implanted elements is controlled so that the dose does not render the substrate amorphous and prevent its relaxation. In step S2 (FIG. 6B), ion implantation 106 of silicon atoms 105a (i.e., implanting ionized silicon atoms) may be carried out, for example, to obtain a maximum concentration of silicon atoms between 1×10²⁰ atoms/cm³ and 5×10²¹ atoms/cm³ close to the maximum implantation zone 105. Next, a strained silicon layer 107 may be formed on the layer 102, for example by epitaxy (FIG. 6C) (step S3). According to the SMART-CUT® technique, implantation 108 of species such as, for example, helium and/or hydrogen, may be carried out in the SiGe layer 102 to form a zone of weakness 109 (FIG. 6D) (step S4). The surface of the sSi layer 107 may then be brought into intimate contact (e.g., by bonding) with a support substrate or receiving substrate 112. The receiving substrate 112 may have a base substrate 111 (e.g., silicon) with a buried oxide layer 110 (BOX) forming the insulating layer (FIG. 6E) (step S5). Alternatively, or supplementally, the oxide layer may be formed by deposition on the sSi layer 107. In one embodiment, the thickness of the buried oxide layer (BOX) may be between 500 Å and 1600 Å, more preferably, between 1300 Å and 1500 Å.

The SiGe layer 102 may then be detached or split at the zone 109 weakened by helium and/or hydrogen implantation, thereby leaving a remaining portion 102a of the layer 102 located between the zone of weakness 109 and the SiGe layer 102/sSi layer 107 interface (FIG. 6F, step S6). Splitting may be provoked by annealing at about 500° C. carried out over a period of about 30 minutes. A finishing step can remove the remaining portion 102a of SiGe (e.g., by selective etching, polishing/planarization, etc.) and provide the sSi layer with a good surface quality (FIG. 6G, step S7). In one embodiment, the finishing step may also comprise forming an insulating layer on the sSi layer. Moreover, a stabilization anneal at about 800° C. may be carried out over a period of about 30 minutes to about 1 hour.

Implantation 106 (step S2) may also be carried out after the step of forming the strained silicon layer 107 on the layer 102 (step S2′ in FIG. 7) or after the step 108 for implanting helium and/or hydrogen into the SiGe layer 102 to form the zone of weakness 109 (step S2″ in FIG. 7). Implantation 106 (step S2, S2′ or S2″) may involve implanting silicon atoms and may be carried out at an implantation energy between 10 keV and 150 keV at an implantation dose between 5×10¹⁴ atoms/cm² and 5×10¹⁵ atoms/cm². By enriching the SiGe layer 102 with interstitial defects by implanting silicon atoms, the diffusion of elemental germanium in the SiGe layer is prevented and, as a result, the passage of elemental germanium into the sSi layer 107 is prevented. The selectivity of etching of the remaining SiGe layer may thereby be substantially increased, which can significantly limit the appearance of defects and degradation of the surface quality of the sSi layer following etching.

In a second exemplary method, enrichment of interstitials of the SiGe layer by the injection of additional elements may be carried out by a step of oxidizing the surface of the substrate. Oxidation of a substrate comprising the SiGe layer will cause interstitial silicon atoms to be injected from the surface, thus allowing the recombination of vacancies (created by implanting the helium and/or hydrogen during creation of the zone of weakness for splitting) with the interstitials and avoiding the diffusion of Ge by a vacancy mechanism.

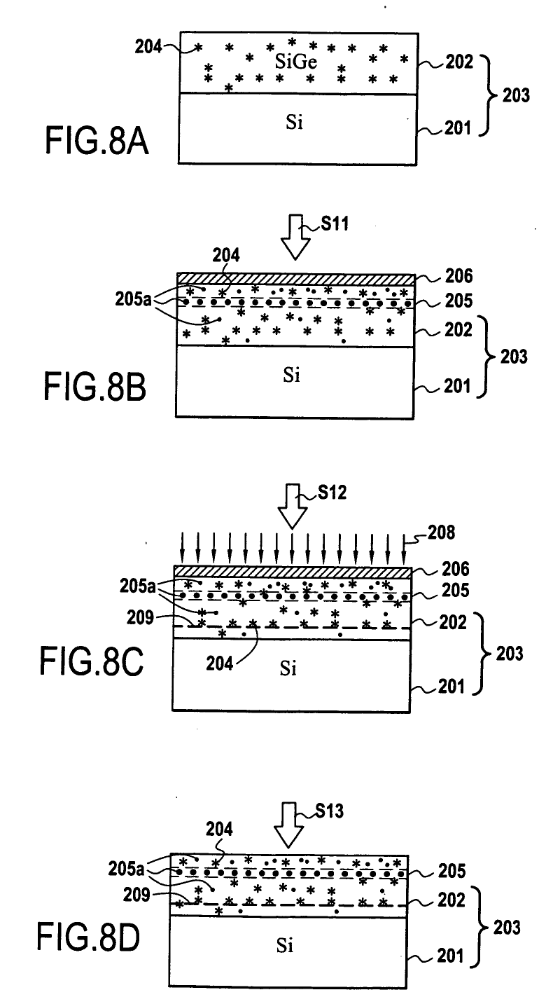

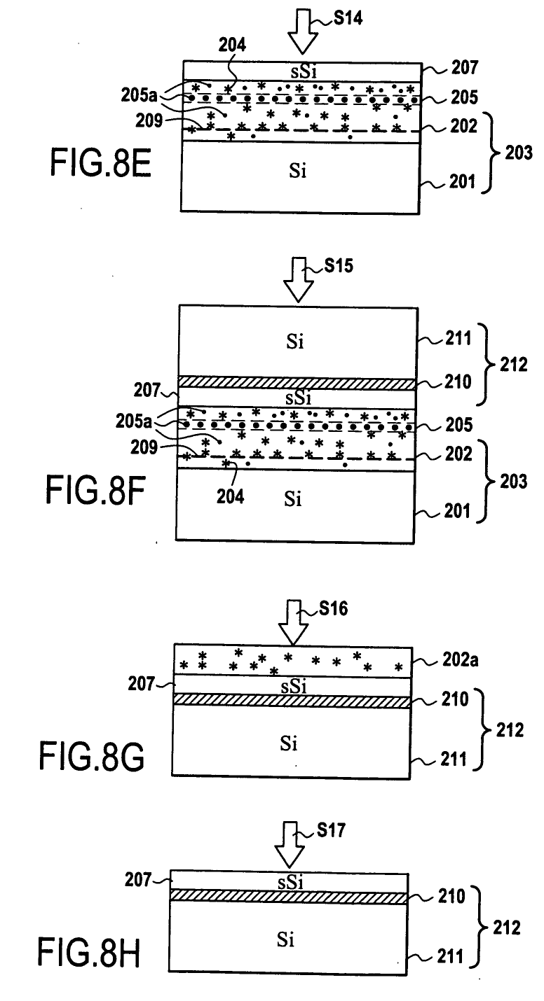

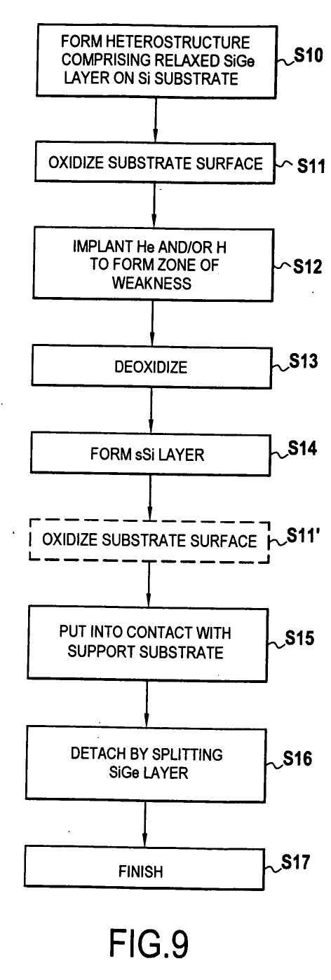

FIGS. 8A to 8H and 9 illustrates an implementation of the second method applied during the production of a wafer of the sSOI type by the SMART-CUT® technique. Step S11 may comprise forming a heterogeneous structure 203, shown in FIG. 8A, which may include a support substrate 201 of silicon and a relaxed SiGe layer 202 formed from a SiGe buffer layer (not shown). Any method known by those skilled in the art may be used to create the heterogeneous structure. The layer 202 may comprise a quantity of elemental germanium 204 between about, for example, 20% and 50% of the composition of the SiGe layer 202. The SiGe layer may have a thickness between, for example, 0.1 μm and 1 μm.

The surface of the SiGe layer 202 may be oxidized to inject interstitial silicon atoms 205a and to oversaturate the layer with the interstitial silicon atoms in a zone 205. The zone 205 may capture the vacancies introduced during the ion implantation step (FIG. 8B; step S11). In this way, a thin layer of oxide 206 may be formed on the surface of the SiGe layer 202. The substrate or heterostructure 203 may, for example, be oxidized by means of an anneal carried out between, for example, 350° C. and 450° C. in a stream of oxygen for a period of 10 minutes to 1 hour. The oxidation can inject an equivalent dose of interstitial silicon atoms between, for example, 1×10¹³ atoms/cm³ and 1×10¹⁴ atoms/cm³.

Using the well known SMART-CUT® technique, implantation 208 of helium and/or hydrogen may be carried out in the SiGe layer 202 to form a zone of weakness 209 (FIG. 8C) (step S12). In the case in which the oxidizing step is carried out before forming the strained silicon layer, a deoxidation step may be carried out (by immersion in hydrofluoric acid (HF) for example) after the oxide formation heat treatment to eliminate the thin oxide layer 206 formed on the surface of the layer 202 (FIG. 8D) (step S113). Thereafter, a strained silicon layer 207 may be formed on the layer 202, for example, by epitaxy (FIG. 8E; step S14). The surface of the sSi layer 207 may then be brought into intimate contact (e.g., by bonding) with a support or receiving substrate 212. The support or receiving substrate 212 may comprise a base substrate 211 (e.g., formed from silicon) with a buried oxide (BOX) layer 210 forming the insulating layer (FIG. 8F; step S15). Alternatively or supplementally, the oxide layer may be formed by deposition onto the sSi layer 207. The buried oxide layer (BOX) may typically have a thickness of between 500 Å and 1600 Å, more preferably, between 1300 Å and 1500 Å.

The SiGe layer 202 may then be detached by splitting at the zone 209 weakened by implanting helium and/or hydrogen, leaving a remaining portion 202a of the layer 202 located between the zone of weakness 209 and the SiGe layer 202/sSi layer 207 (FIG. 8G; step S116). Splitting may by provoked by annealing at about 500° C. for a period of about 30 minutes. A finishing step may be performed to remove the remaining portion 202a of SiGe (by selective chemical etching, polishing/planarization, etc) and to provide the sSi layer with a good surface quality (FIG. 8H, step S17). The finishing step may also comprise forming an insulating layer on the sSi layer. Additionally, a stabilization anneal at about 800° C. may be performed for a period of about 30 minutes to about 1 hour. The oxidation step (step S11) may also be performed after the step of forming the strained silicon layer 207 on the layer 202 (step S11′ in FIG. 9). In contrast to a method in which oxidation is carried out before forming the sSi layer 207, the deoxidation step (step S13) may not be necessary since an insulating layer corresponding to a buried oxide layer (BOX) in the final structure may be subsequently deposited.

The Si atoms injected during step S11 (or S11′) will become interstitials and, then, may recombine with the vacancies present near the helium and/or hydrogen implantation. This can reduce the flow of vacancies at the interface between the SiGe layer and the sSi layer and, consequently, may reduce diffusion after applying subsequent heat treatments (e.g., forming an oxide layer, splitting anneal, stabilization anneal, etc). The enrichment of the SiGe layer 202 with interstitial defects by oxidation prevents the diffusion of elemental germanium in the SiGe layer. In this way, the passage of elemental germanium into the sSi layer 207 may also be prevented. The etching selectivity of the remaining SiGe layer may be substantially increased, thereby, significantly limiting the appearance of defects and degradation of the surface quality of the sSi layer following etching.

While the foregoing description and drawings represent the preferred embodiments of the present invention, it will be understood that various additions, modifications and substitutions may be made therein without departing from the spirit and scope of the present invention as defined in the accompanying claims. In particular, it will be clear to those skilled in the art that the present invention may be embodied in other specific forms, structures, arrangements, proportions, and with other elements, materials, and components, without departing from the spirit or essential characteristics thereof. One skilled in the art will appreciate that the invention may be used with many modifications of structure, arrangement, proportions, materials, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being indicated by the appended claims, and not limited to the foregoing description.

What is claimed is:

1. A method for reducing vacancy diffusion during fabrication of a semiconductor structure, which comprises:
providing a semiconductor structure comprising at least a first layer of semiconductor material on a second layer of material, wherein the semiconductor material includes elements that are capable of diffusing into the second or an adjacent layer by a vacancy diffusion mechanism; and
injecting additional elements into the semiconductor material of the first layer in an amount sufficient to create interstitial defects therein to limit or prevent vacancy diffusion of the elements into the second layer.

2. The method of claim 1, wherein the injecting of the additional elements comprises implanting silicon atoms in the semiconductor material at an implantation energy of between 10 keV and 150 keV and an implantation dose of between 5×1014 atoms/cm2 and 5×1015 atoms/cm2 to enrich the first layer.

3. The method of claim 2, wherein the silicon-enriched layer has a concentration of silicon atoms between 1×1020 atoms/cm3 and 5×1021 atoms/cm3.

4. The method of claim 1 which further comprises forming a third layer of material on the first layer by epitaxy, wherein the third layer is a strained silicon layer.

5. The method of claim 4 which further comprises forming a zone of weakness in the first layer.

6. The method of claim 5 wherein the injecting of the additional elements comprises oxidizing the surface of the first layer before forming the third layer and before forming the layer of weakness.

7. The method of claim 5, wherein the injecting of the additional elements comprises oxidizing the surface of the first layer after forming the third layer and before forming the layer of weakness.

8. The method of claim 5 which further comprises providing a receiving substrate having a base substrate and a buried oxide layer; and attaching the receiving substrate to the third layer.

9. The method of claim 8, wherein the buried oxide layer has a thickness of between 500 Å and 1600 Å and which further comprises attaching a fourth layer of material to the third layer.

10. The method of claim 9, wherein the step of forming a zone of weakness comprises implanting atoms into the first layer, wherein the species is one of hydrogen or helium atoms and which further comprises implanting additional elements after implanting the hydrogen or helium atoms.

11. The method of claim 8, wherein the zone of weakness is provided between first and second portions of the first layer, wherein the first portion is positioned adjacent the second layer, and the method further comprises detaching the first portion of the first layer and the second layer from the second portion of the first layer at the zone of weakness.

12. The method of claim 11, wherein the step of detaching further comprises annealing at about 500° C. for about 30 minutes and which further comprises removing the second portion of the first layer from the third layer by etching.

13. The method of claim 8, wherein the injecting of the additional elements comprises implanting silicon atoms in the semiconductor material and the first layer has a surface, and the method further comprises selecting at least one of an implantation energy and an implantation dose during the implantation of the silicon atoms to form a silicon-enriched layer located between the zone of weakness and the surface of the first layer.

14. The method of claim 4 which further comprises forming an insulating layer on the third layer and then performing stabilization annealing at about 800° C. for a period of between about 30 minutes and about 1 hour.

15. The method of claim 1, wherein the first layer is made of SiGe and the second layer is made of silicon, and the method further comprises providing the first layer with a thickness of between 0.1 μm and 1 μm and with a quantity of elemental germanium between 20% and 50%.

16. The method of claim 1, wherein the first layer has a surface and wherein the injecting of the additional elements comprises oxidizing the surface of the first layer by annealing the semiconductor structure in a stream of oxygen for a period of time sufficient to form an oxidized surface on the first layer.

17. The method of claim 16, wherein the annealing is conducted at between about 350° C. and 450° C. for a period of time between 10 minutes and 1 hour.

18. The method of claim 16 which further comprises performing a deoxidation step to remove the oxidized surface of the first layer.

19. The method of claim 18, wherein the deoxidation step comprises immersing at least a portion of the oxidized surface of the first layer in hydrofluoric acid.

20. A semiconductor structure comprising:
at least a first layer of semiconductor material on a second layer of material, wherein the semiconductor material includes elements that are capable of diffusing into the second or an adjacent layer by a vacancy diffusion mechanism; and
additional elements injected into the semiconductor material of the first layer in an amount sufficient to create interstitial defects therein to limit or prevent vacancy diffusion of the elements into the second layer.

21. The semiconductor structure of claim 20 which further comprises a third layer of an epitaxially grown material on the first layer.

22. The semiconductor structure of claim 20 which further comprises a zone of weakness in the first layer.

23. The semiconductor structure of claim 20 which further comprises a fourth layer of material upon the third layer.

24. The semiconductor structure of claim 20, wherein the first layer is made of SiGe and the second layer is made of silicon, and the first layer has a thickness of between 0.1 μm and 1 μm and contains a quantity of elemental germanium between 20% and 50%.
